(19) United States
(12) Patent Application Publication
(10) Pub. No.: US 2026/0143976 A1
(43) Pub. Date: May 21, 2026

(54) MEMORY DEVICE AND METHOD OF MANUFACTURING THE SAME

(71) Applicant: Samsung Electronics Co., Ltd., Suwon-si (KR)

(72) Inventors: Eunji YANG, Suwon-si (KR); Junyoung KWON, Suwon-si (KR); Changhyun KIM, Suwon-si (KR)

(73) Assignee: Samsung Electronics Co., Ltd., Suwon-si (KR)

(21) Appl. No.: 19/300,211

(22) Filed: Aug. 14, 2025

(30) Foreign Application Priority Data
Nov. 15, 2024 (KR) 10-2024-0163348
Aug. 12, 2025 (KR) 10-2025-0111535

(51) Int. Cl. H10N 70/00; H10B 63/00

(52) U.S. Cl. CPC H10N 70/8825; H10B 63/30; H10N 70/021; H10N 70/8822

(57) ABSTRACT

A semiconductor device includes a plurality of first gate electrodes, a channel layer provided to surround at least one of the plurality of first gate electrodes; and a first gate via extending in a second direction and connected to one end of each of the plurality of first gate electrodes to connect the plurality of first gate electrodes to each other.

### CROSS-REFERENCE TO RELATED APPLICATION

This application is based on and claims priority under 35 U.S.C. § 119 to Korean Patent Applications Nos. 10-2024-0163348, filed on Nov. 15, 2024, and 10-2025-0111535, filed on Aug. 12, 2025, in the Korean Intellectual Property Office, the disclosure of which is incorporated by reference herein in its entirety.

### BACKGROUND

### 1. Field

The disclosure relates to a semiconductor device and a method of manufacturing the semiconductor device.

### 2. Description of the Related Art

With the refinement of semiconductor processes, the sizes of transistors are decreasing and an area where a gate electrode is in contact with a channel are decreasing, and accordingly, issues caused by a short channel effect may occur. A gate-all-around (GAA) structure has been developed to reduce the short channel effect and improve gate control. A transition metal dichalcogenide (TMD) material has sufficient and/or excellent scaling characteristics and may be advantageous for implementing a multi-bridge channel field effect transistor (MBCFET) having a GAA structure.

However, there are several process issues that may make it more difficult to directly apply silicon-based process to the TMD material. For example, when a two-dimensional TMD material is used as a channel, the two-dimensional TMD material may be vulnerable to a subsequent process due to being relatively thin, which may lead to a decrease in device performance and/or an increase in dispersion.

### SUMMARY

Provided is a semiconductor device having a dual gate structure and a method of manufacturing the semiconductor device.

Additional aspects will be set forth in part in the description which follows and, in part, will be apparent from the description, or may be learned by practice of the presented embodiments.

According to an aspect of the disclosure, a semiconductor device includes a, a source electrode on a substrate, a drain electrode on the substrate and spaced apart from the source electrode, a channel layer connecting the source electrode to the drain electrode and including a two-dimensional material, a plurality of first gate electrodes on the channel layer and at least partially between the source electrode and the drain electrode, the plurality of first gate electrodes extending in a first direction, and separated from each other in a second direction that is different from the first direction and perpendicular to the substrate, and a first gate via extending in the second direction and connected to one end of each of the plurality of first gate electrodes such that the plurality of first gate electrodes are electrically connected to each other.

The plurality of first gate electrodes may be connected to one surface of the first gate via and may not be connected to a surface opposite to the one surface.

The semiconductor device may further include a plurality of second gate electrodes extending in the first direction and respectively between the plurality of first gate electrodes.

The semiconductor device may further include a second gate via connected to the plurality of second gate electrodes such that the plurality of second gate electrodes are electrically connected to each other.

The channel layer may be between the plurality of first gate electrodes.

The channel layer may surround four side surfaces of at least one of the plurality of the first gate electrodes.

The channel layer may be between corresponding ones of the plurality of first gate electrodes and the plurality of second gate electrodes.

The semiconductor device may further include a first gate insulating layer between the plurality of first gate electrodes and the channel layer.

The first gate insulating layer may surround four side surfaces of at least one of the plurality of first gate electrodes.

The semiconductor device may further include a second gate insulating layer between the plurality of second gate electrodes and the channel layer.

The channel layer may include three or less layers.

The channel layer may include a transition metal dichalcogenide (TMD).

The TMD may include one of MoS₂, WSe₂, MoSe₂, and WS₂.

According to another aspect of the disclosure, a method of manufacturing a semiconductor device includes forming, on a substrate, a plurality of first gate electrodes such that the plurality of first gate electrodes extend in a first direction and are separated from each other in a second direction that is different from the first direction and perpendicular to the substrate, forming a first gate via such that the first gate via extends in the second direction and electrically connects the plurality of first gate electrodes to each other, forming a first gate insulating layer such that the first gate insulating layer surrounds the first gate via and at least one of the plurality of first gate electrodes, forming a channel layer on the first gate insulating layer, and forming a source electrode and a drain electrode such that the source electrode and the drain electrode are spaced from each other with the plurality of first gate electrodes therebetween.

The method may further include forming a second gate insulating layer such that the second gate insulating layer is in contact with the channel layer, and forming a plurality of second gate electrode extending in the first direction and respectively between the plurality of first gate electrodes.

The forming of the source electrode and the drain electrode may include forming a dummy layer surrounding the channel layer, forming a contact hole by etching the dummy layer through a dry etching process, expanding the contact hole by etching the dummy layer through an isotropic etching process, and depositing a metal into the contact hole.

The dummy layer may include at least one of silicon oxide, aluminum oxide, or silicon nitride.

The method of manufacturing the semiconductor device may further include forming a second gate via such that the second gate via electrically connects the plurality of second gate electrodes to each other.

The channel layer may be provided to surround four side surfaces of each of the plurality of first gate electrodes.

The channel layer may include a transition metal dichalcogenide (TMD).

### BRIEF DESCRIPTION OF THE DRAWINGS

The above and other aspects, features, and advantages of certain embodiments will be more

apparent from the following description taken in conjunction with the accompanying drawings, in which:

FIG. 1 is a perspective view illustrating a semiconductor device according to at least one embodiment;

FIG. 2 is a cross-sectional view taken along line A1-A1′ of FIG. 1;

FIG. 3 is a cross-sectional view taken along line B-B′ of FIG. 1;

FIG. 4 is a perspective view illustrating a semiconductor device according to at least one embodiment;

FIG. 5 is a cross-sectional view taken along line A2-A2′ of FIG. 4;

FIG. 6A to FIG. 6J illustrate a method of manufacturing a semiconductor device, according to at least one embodiment;

FIG. 7A to FIG. 7D illustrate a part of a method of manufacturing a semiconductor device, according to at least one embodiment;

FIG. 8 is a schematic block diagram of a display driver integrated circuit (DDI) including a field effect transistor and a display device including the DDI, according to at least one embodiment;

FIG. 9 is a block diagram of an electronic system including a semiconductor device according to at least one embodiment; and

FIG. 10 is a block diagram of an electronic system including a semiconductor device according to at least one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device and a method of manufacturing the semiconductor device according to various embodiments are described in detail with reference to the attached drawings. In the following drawings, the same reference numerals refer to the same components, and a size of each component in the drawings may be exaggerated for the sake of clear and convenient description. Also, the following embodiments to be described are merely examples, and various modifications may be made from the embodiments. Additionally, when the terms “about” or “substantially” are used in this specification in connection with a numerical value and/or geometric term, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Hereinafter, what is described as an “upper portion” or “on, over, or above” may also include not only “on” but also “above” and “over”. Additionally, spatially relative terms, such as above, below, etc. are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly. Singular expressions include plural expressions unless the context clearly indicates otherwise. In addition, when a portion “includes” a certain component, this means that other components may be further included rather than excluding other components unless specifically stated to the contrary.

Use of a term “the” and similar reference terms may correspond to both the singular and the plural. Steps constituting a method may be performed in any suitable order unless there is a clear statement that the steps should be performed in the order described or contrary to the order and are not limited thereto.

Connection or connection members of lines between configuration elements illustrated in the drawings exemplarily represent functional connections and/or physical or circuit connections and may be represented as alternative or additional various functional connections, physical connections, or circuit connections in an actual apparatus. Also, the terms such as “unit” and “module” described in the specification mean units that are configured to process at least one function or operation, and may be implemented as processing circuitry such as hardware, software, or a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc., unless expressly indicated otherwise.

Use of all examples or all example terms is merely for describing technical ideas in detail, and the scope of claims is not limited by the examples or the example terms unless limited by the claims.

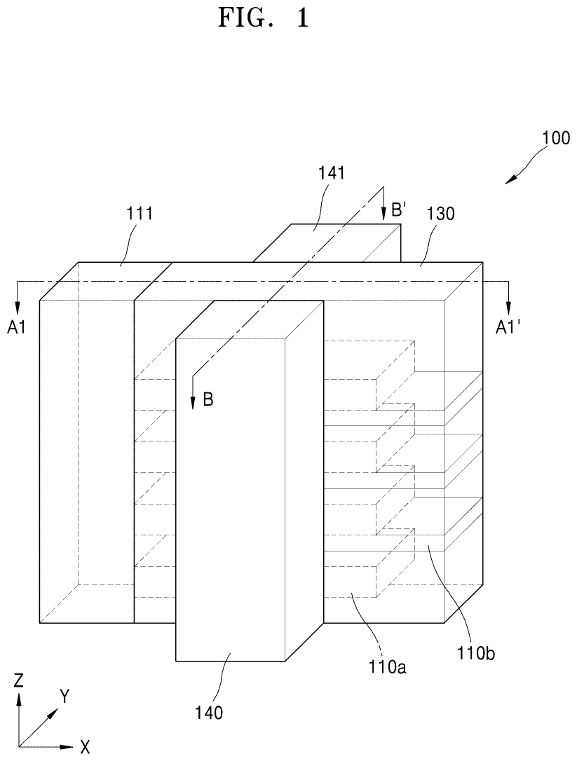

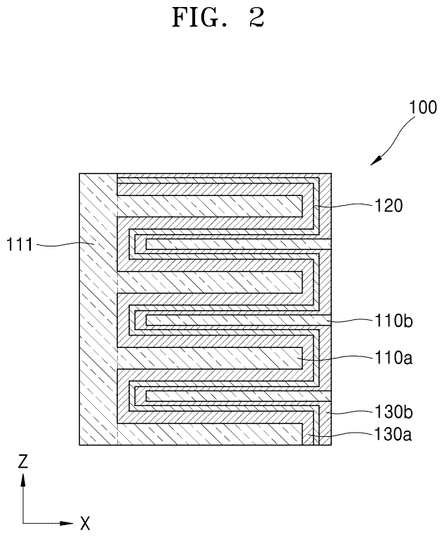

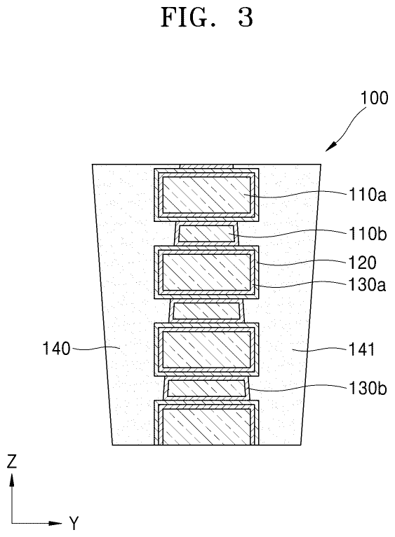

FIG. 1 is a perspective view illustrating a semiconductor device according to at least one embodiment. FIG. 2 is a cross-sectional view taken along line A1-A1′ of FIG. 1 and FIG. 3 is a cross-sectional view taken along line B-B′ of FIG. 1.

Referring to FIG. 1, a semiconductor device 100 may include a plurality of first gate electrodes 110a extending in a first direction (the x direction) and separated from each other in a second direction (the z direction) that is different from the first direction (the x direction) and away from (e.g., perpendicular to) a substrate (not illustrated), a plurality of second gate electrodes 110b extending in the first direction (the x direction) and respectively provided between the plurality of first gate electrodes 110 a, and a first gate via 111 extending in the second direction (the z direction) and provided to connect the plurality of first gate electrodes 110a to each other.

Although FIG. 1 illustrates four first gate electrodes 110a and three second gate electrodes 110b, the disclosure is not limited thereto. The plurality of first gate electrodes 110a may be two or more, and/or the plurality of second gate electrodes 110b may be one or more.

The plurality of first gate electrodes 110a may each include a metal material and/or a conductive oxide. The metal material may include at least one selected from, for example, Au, Ti, TiN, TaN, W, Mo, WN, Pt, and Ni. The conductive oxide may include, for example, indium tin oxide (ITO), indium zinc oxide (IZO), and/or the like.

The plurality of second gate electrodes 110b may each include a metal material and/or a conductive oxide. The metal material may include at least one selected from, for example, Au, Ti, TiN, TaN, W, Mo, WN, Pt, and Ni. The conductive oxide may include, for example, ITO, IZO, and/or the like. The metal material and/or conductive oxide of the plurality of second gate electrodes 110b may be different from the metal material and/or conductive oxide of the plurality of first gate electrodes 110a.

The first gate via 111 may connect one end of each of the plurality of first gate electrodes 110a to one end of each of the plurality of first gate electrodes 110a. The plurality of first gate electrodes 110 a may be connected to one surface of the first gate via 111 and may not be connected to a surface opposite to the one surface of the first gate via 111. The first gate via 111 may include the same material as the plurality of first gate electrodes 110 a. The first gate via 111 may include a metal material or a conductive oxide. The metal material may include at least one selected from, for example, Au, Ti, TiN, TaN, W, Mo, WN, Pt, and Ni. The conductive oxide may include, for example, ITO, IZO, and/or the like.

The plurality of first gate electrodes 110a and the plurality of second gate electrodes 110b may be surrounded by a gate insulating layer 130. The gate insulating layer 130 may surround at least one of the plurality of first gate electrodes 110a. The gate insulating layer 130 may surround at least one of the plurality of second gate electrodes 110b. The gate insulating layer 130 may electrically insulate the plurality of first gate electrodes 110a from the plurality of second gate electrodes 110b. The gate insulating layer 130 may include a first gate insulating layer 130a (see FIG. 2) and a second gate insulating layer 130b (see FIG. 2).

Referring to FIG. 2 and FIG. 3, the semiconductor device 100 includes a channel layer 120 surrounding each of the plurality of first gate electrodes 110 a, and the first gate via 111 does not overlap the channel layer 120 in the second direction (the z direction). However, in at least some embodiments, due to limitations in a process, the first gate via 111 may partially overlap the channel layer 120 in the second direction (the z direction).

The channel layer 120 may be formed on the gate insulating layer 130. Accordingly, the channel layer 120 may surround the first gate electrode 110a, preferably surround four side surfaces of the first gate electrode 110a. The channel layer 120 may be formed between the first gate electrode 110a and the second gate electrode 110b which are adjacent to each other. Thus, a gating effect may be improved.

The channel layer 120 may be formed on one surface of the first gate via 111 and may not be formed on a surface opposite to the one surface. The channel layer 120 may be formed in at least part of one surface of the first gate via 111, and the first gate electrode 110 a may be connected to the other part of the one surface.

The channel layer 120 may surround four side surfaces of the first gate electrode 110a. The channel layer 120 may extend in the first direction (the x direction) between the first gate electrode 110a and the second gate electrode 110b. A plurality of channel layers 120, each surrounding each of the four side surfaces of the plurality of first gate electrodes 110a, may be connected to each other as one layer. In order for the plurality of channel layers 120 to be connected to each other as one layer, a part of each of the plurality of channel layers 120 may extend in the second direction (the z direction). The channel layer 120 may surround the second gate electrode 110b.

Although the channel layer 120 is illustrated as a single layer, the disclosure is not limited thereto, and the channel layer 120 may include multiple layers. The channel layer 120 may include, for example, three or less layers.

The channel layer 120 may include, for example, a transition metal dichalcogenide (TMD). The TMD may be, for example, MX₂, wherein M represents a transition metal and X represents a chalcogen element. For example, M may be Mo, W, Nb, V, Ta, Ti, Zr, Hf, Tc, Re, and/or the like, and X may be S, Se, Te, and/or the like. Therefore, the TMD may include, for example, MoS₂, Wse₂, MoSe₂, WS₂, and/or the like.

A space between the channel layer 120 and the plurality of first gate electrodes 110a may be filled with the first gate insulating layer 130a. The first gate insulating layer 130a may surround each of the plurality of first gate electrodes 110a. The first gate insulating layer 130a may insulate between the plurality of first gate electrodes 110a and the channel layer 120 and may prevent or reduce a leakage current.

The first gate insulating layer 130a may include a high-k material. The first gate insulating layer 130a may include, for example, aluminum oxide, hafnium oxide, zirconium oxide, zirconium hafnium oxide, lanthanum oxide, and/or the like. However, the disclosure is not limited thereto.

The second gate insulating layer 130b may surround the plurality of second gate electrodes 110b. The second gate insulating layer 130b may be in contact with the channel layer 120. The second gate insulating layer 130b may be provided between the plurality of second gate electrodes 110b and the channel layer 120, insulate between the plurality of second gate electrode 110b and the channel layer 120, and prevent or reduce a leakage current.

The second gate insulating layer 130b may include a high-k material. The second gate insulating layer 130b may include, for example, aluminum oxide, hafnium oxide, zirconium oxide, zirconium hafnium oxide, lanthanum oxide, and/or the like. However, the disclosure is not limited thereto.

The semiconductor device 100 may further include a source electrode 140 and a drain electrode 141 that are separated from each other with the plurality of first gate electrodes 110a and the plurality of second gate electrodes 110b therebetween. The plurality of first gate electrodes 110a and the plurality of second gate electrodes 110b may extend in the first direction (the x direction), and the source electrode 140 may be separated from the drain electrode 141 in a third direction (the y direction) with the plurality of first gate electrodes 110a and the plurality of second gate electrodes 110b therebetween.

The source electrode 140 may be separated from the drain electrode 141 with the channel layer 120 therebetween. The channel layer 120 may extend in the first direction (the x direction), and the source electrode 140 may be separated from the drain electrode 141 in the third direction (the y direction) different from the first direction (the x direction) with the channel layer 120 therebetween. The channel layer 120 is configured to be a path through which a current flows between the source electrode 140 and the drain electrode 141 when gating effect is turned on. The channel layer 120 may be in direct contact with the source electrode 140 and the drain electrode 141. However, the channel layer 120 is not limited thereto and may also be connected to the source electrode 140 and the drain electrode 141 through another medium.

The source electrode 140 and the drain electrode 141 may each include an electrical conductivity material, such as a metal material. For example, the source electrode 140 and the drain electrode 141 may each include a metal, such as magnesium (Mg), aluminum (Al), scandium (Sc), titanium (Ti), vanadium (V), chromium (Cr), manganese (Mn), nickel (Ni), copper (Cu), zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), an alloy thereof, and/or the like.

The semiconductor device 100 according to the embodiment may have a dual gate structure in which the channel layer 120 is provided between the first gate electrode 110a and the second gate electrode 110b, and thus, the semiconductor device 100 may be improved in performance.

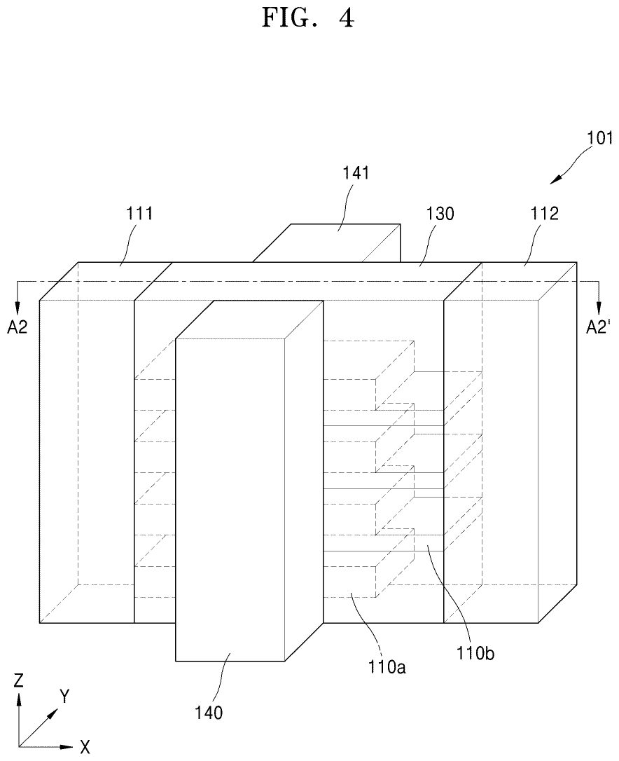

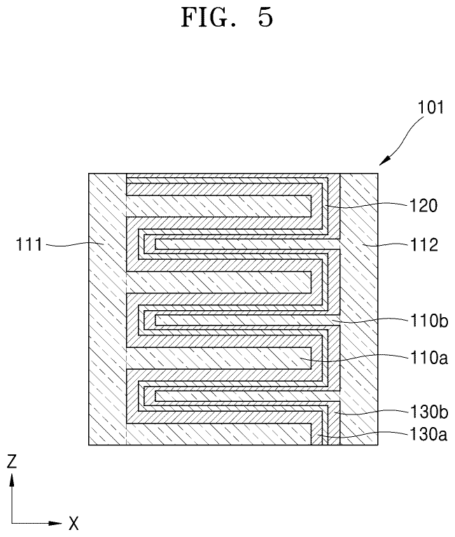

FIG. 4 is a perspective view illustrating a semiconductor device according to at least one embodiment, and FIG. 5 is a cross-sectional view taken along line A2-A2′ of FIG. 4.

Referring to FIG. 4 and FIG. 5, a semiconductor device 101 may include a plurality of first gate electrodes 110a extending in a first direction (the x direction) and separated from each other in a second direction (the z direction) different from the first direction (the x direction), a plurality of second gate electrodes 110b extending in the first direction (the x direction) and respectively provided between the plurality of first gate electrodes 110a, a channel layer 120 surrounding each of the plurality of first gate electrodes 110a and the plurality of second gate electrodes 110b, a first gate via 111 provided to connect the plurality of first gate electrodes 110 a to each other, and a second gate via 112 provided to connect the plurality of second gate electrodes 110 b to each other.

The semiconductor device 101 may be the same as (or substantially similar to) the semiconductor device 100 described above with reference to FIG. 1 to FIG. 3, except that the semiconductor device 101 further includes the second gate via 112. In describing the semiconductor device 101 with reference to FIG. 4 and FIG. 5, the descriptions substantially similar to the descriptions given above with reference to FIG. 1 to FIG. 3 may be omitted.

The second gate via 112 may not overlap the channel layer 120 in the second direction (the z direction). However, due to limitations in a process, in at least some embodiments, the second gate via 112 may partially overlap the channel layer 120 in the second direction (the z direction). The second gate via 112 may be connected to one end of each of the plurality of second gate electrodes 110b.

In at least some embodiments, the second gate via 112 may include the same (or a substantially similar) material as the first gate via 111. The second gate via 112 may include a metal material or a conductive oxide. The metal material may include at least one selected from, for example, Au, Ti, TiN, TaN, W, Mo, WN, Pt, and Ni. The conductive oxide may include, for example, ITO, IZO, and/or the like.

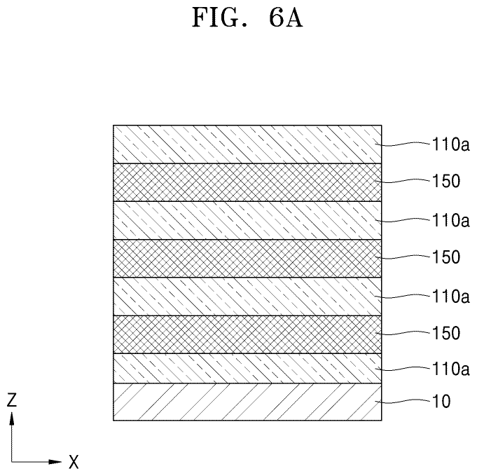

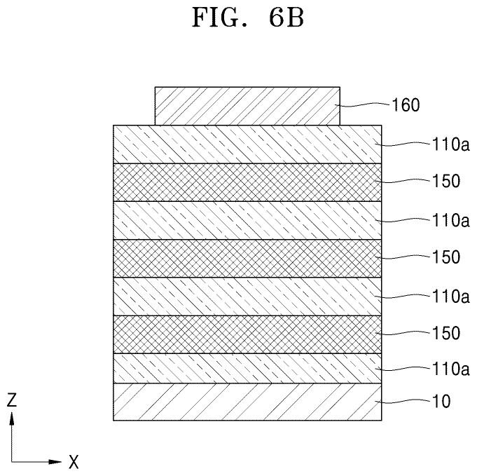

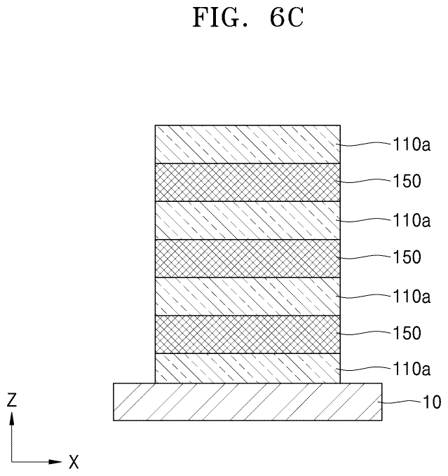

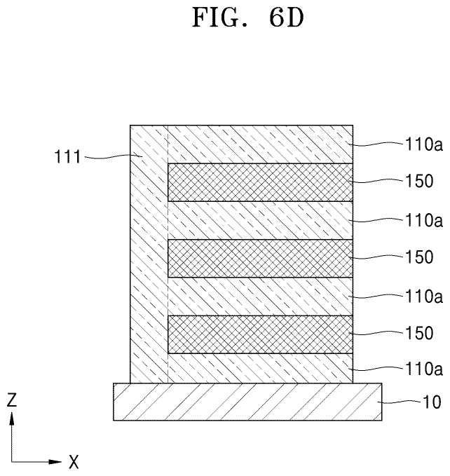

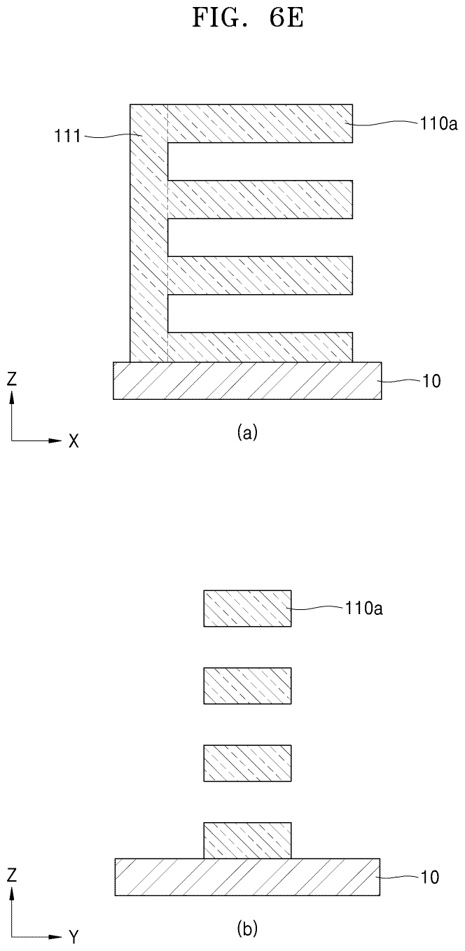

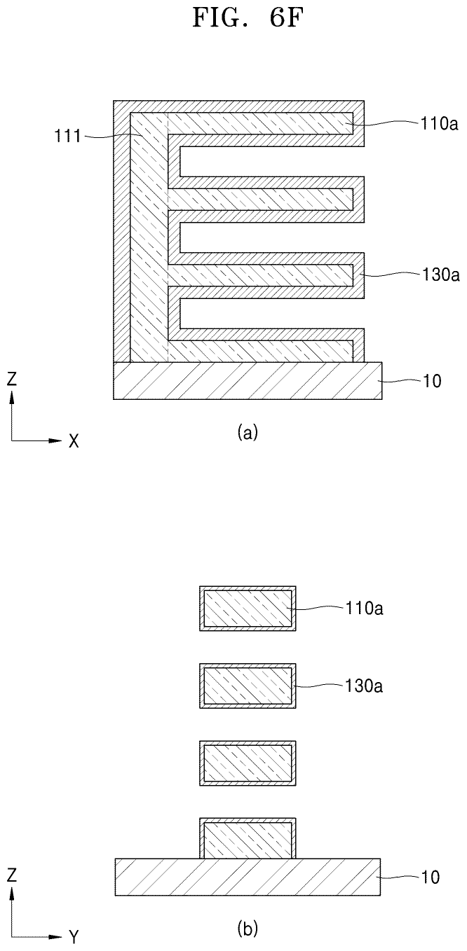

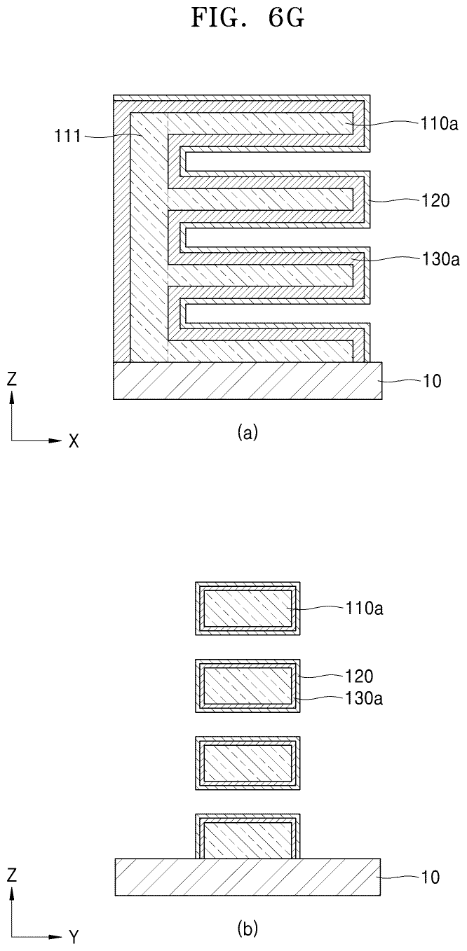

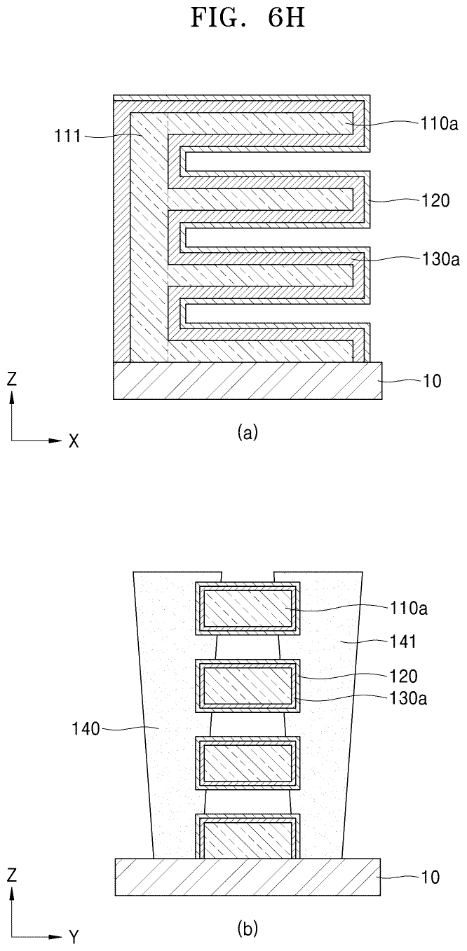

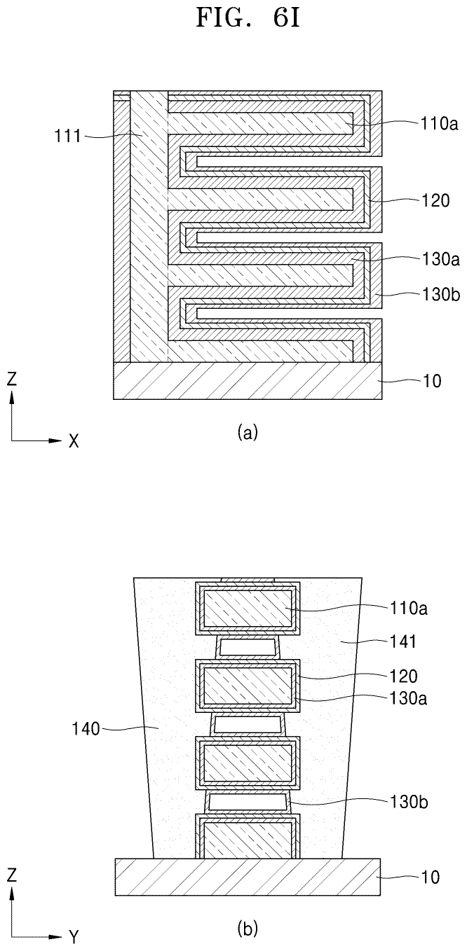

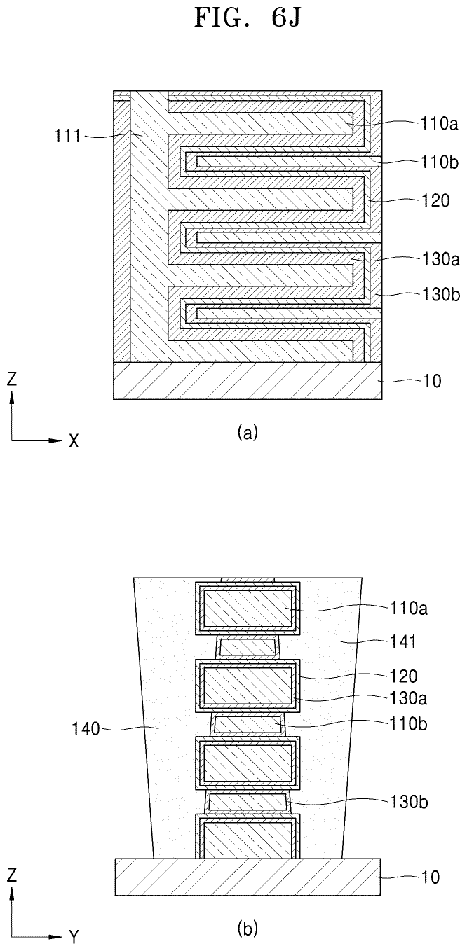

FIG. 6A to FIG. 6J illustrate a method of manufacturing a semiconductor device, according to at least one embodiment. The method of manufacturing the semiconductor device according to the embodiment may indicate a method of manufacturing the semiconductor device 100 of FIG. 1. In describing the method with reference to FIG. 6A to FIG. 6J, the descriptions given above with reference to FIG. 1 to FIG. 3 may be omitted.

Referring to FIG. 6A, a plurality of sacrificial layers 150 and a plurality of first gate electrodes 110a may be alternately stacked in a second direction (the z direction) away from the substrate 10 to form a stack structure. The substrate 10 may be an insulating substrate, or a semiconductor substrate having an insulating layer formed on a surface of the semiconductor substrate. The substrate 10 may include, for example, silicon (Si) (such as single crystal silicon, polycrystalline silicon, or amorphous silicon), a group IV semiconductor (such as germanium (Ge)), a group IV-IV compound semiconductor (such as silicon germanium (SiGe) or silicon carbide (SiC)), and/or a group III-V compound semiconductor, such as gallium arsenide (GaAs), indium arsenide (InAs), or indium phosphide (InP). The substrate 10 may be based on a silicon bulk substrate or may be based on a silicon on insulator (SOI) substrate. The substrate 10 is not limited to a bulk substrate or an SOI substrate and may also be based on an epitaxial wafer, a polished wafer, an annealed wafer, and/or the like. The substrate 10 may include a conductive region, for example, a well doped with an impurity, or various structures doped with impurities. Also, the substrate 10 may be configured as a p-type substrate or an n-type substrate depending on the type of doped impurity ions.

The plurality of sacrificial layers 150 and the plurality of first gate electrodes 110a may each be formed of a material that may be selectively removed depending on etching gas or an etching solution. The plurality of sacrificial layers 150 may each include an inorganic material, such as SiO₂, Al₂O₃, Si₃N₄, poly-Si, or SiGe, or an organic material, such as polymethyl methacrylate (PMMA).

Referring to FIG. 6B and FIG. 6C, a photoresist layer 160 may be formed on an uppermost portion of the stack structure composed of the plurality of sacrificial layers 150 and the plurality of first gate electrodes 110a, and then, the stack structure may be patterned by etching both side surfaces of the stack structure.

Referring to FIG. 6D, a gate via 111 may be formed on one side surface of the stack structure composed of the plurality of sacrificial layers 150 and the plurality of first gate electrodes 110a. The gate via 111 may extend in a second direction (the z direction) to be connected to the plurality of first gate electrodes 110a.

In order to describe a method of manufacturing a semiconductor device, each of FIGS. 6E to 6J illustrates (a) an xz-plane view of the semiconductor device and (b) an yz-plane view of the semiconductor device.

Referring to FIG. 6E, the plurality of sacrificial layers 150 may be removed. By removing the plurality of sacrificial layers 150, the plurality of first gate electrodes 110a may be separated from each other in the second direction (the z direction) away from the substrate 10.

Referring to FIG. 6F, a first gate insulating layer 130a may be formed to surround the gate via 111 and at least one of the plurality of first gate electrodes 110 a. The first gate insulating layer 130a may be formed through, for example, an atomic layer deposition (ALD) process.

Referring to FIG. 6G, a channel layer 120 may be formed to surround at least one of the plurality of first gate electrodes 110a. The channel layer 120 may be formed through a chemical vapor deposition (CVD) process, a metal organic chemical vapor deposition (MOCVD) process, or an ALD process. The first gate insulating layer 130a may be provided between the plurality of first gate electrodes 110a and the channel layer 120.

Referring to FIG. 6H, a source electrode 140 and a drain electrode 141 may be formed to extend in the second direction (the z direction) and may be separated from each other with the plurality of first gate electrodes 110a therebetween.

Referring to FIG. 6I, a second gate insulating layer 130b may be formed to be in contact with the channel layer 120, and a part of the first gate insulating layer 130a and a part of the channel layer 120 may be etched to expose the first gate via 111. The second gate insulating layer 130b may be formed through an ALD process.

Referring to FIG. 6J, a plurality of second gate electrodes 110b extending in a first direction (the x direction) and respectively provided between the plurality of first gate electrodes 110a may be formed. The plurality of second gate electrodes 110b may be formed through an ALD process.

According to the method of manufacturing a semiconductor device, according to at least one embodiment, the gate via 111 may be formed before forming the channel layer 120 to connect the plurality of first gate electrodes 110a to each other, and thus, a process of manufacturing the semiconductor device may be simplified.

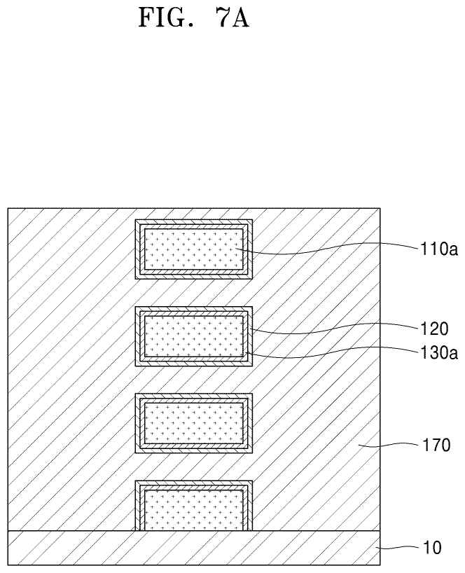

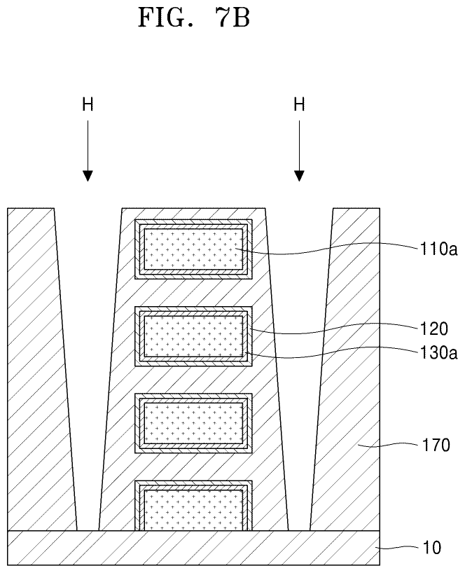

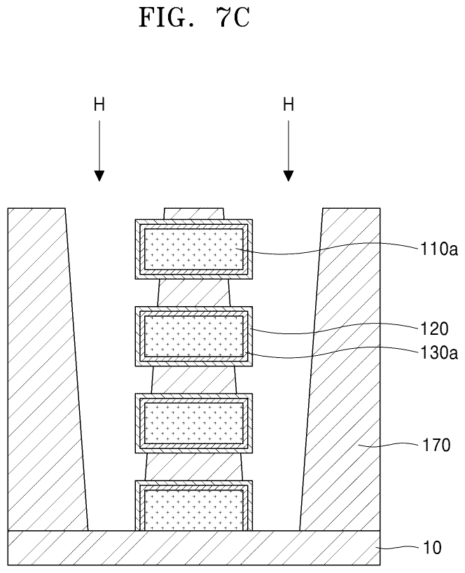

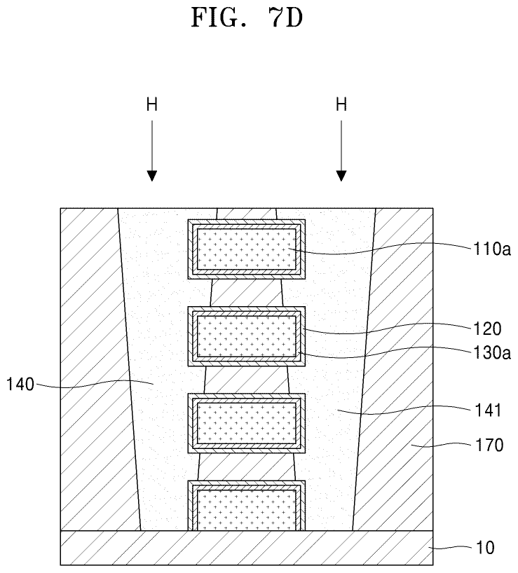

FIG. 7A to FIG. 7D illustrate a part of a method of manufacturing a semiconductor device, according to at least one embodiment. The processes illustrated in FIG. 6A to FIG. 6G may be performed before a process illustrated in FIG. 7A, and the processes illustrated in FIG. 6H to FIG. 6J may be performed after a process illustrated in FIG. 7D.

Referring to FIG. 7A, a dummy layer 170 surrounding the channel layer 120 may be formed. The dummy layer 170 may include an oxide or a nitride. The dummy layer 170 may include, for example, silicon oxide, aluminum oxide, or silicon nitride.

Referring to FIG. 7B, the dummy layer 170 may be etched in a dry etching process to form a contact hole H.

Referring to FIG. 7C, the dummy layer 170 may be etched in an isotropic etching process to expand the contact hole H. Therethrough, the channel layer 120 may be exposed to the outside of the dummy layer 170.

Referring to FIG. 7D, the contact hole H may be filled with a metal to form a source electrode 140 and a drain electrode 141. The source electrode 140 and the drain electrode 141 may each include the same material. Thereafter, the dummy layer 170 may be removed through a wet etching process.

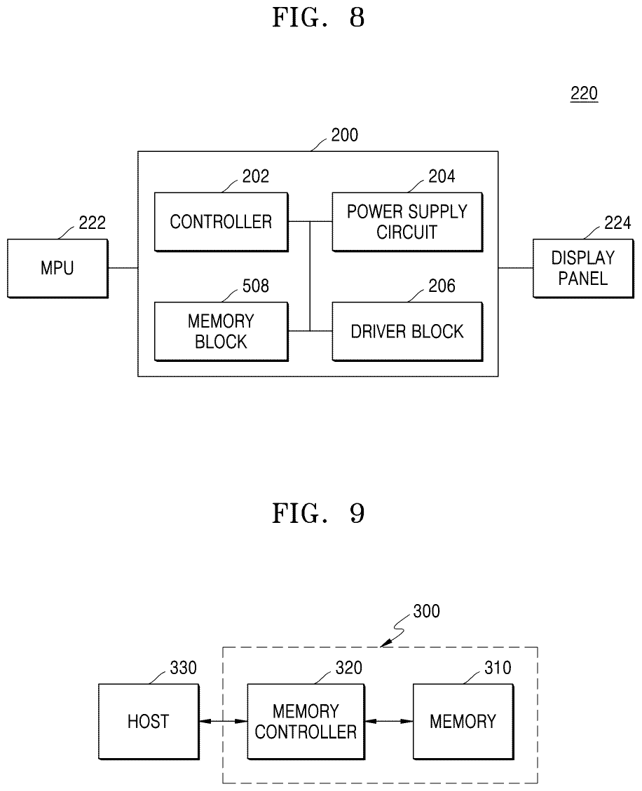

FIG. 8 is a schematic block diagram of a display driver IC (DDI) and a display device including the DDI, according to at least one embodiment.

Referring to FIG. 8, a DDI 200 may include a controller 202, a power supply circuit 204, a driver block 206, and a memory block 208. The controller 202 may receive a command from a main processing unit (MPU) 222, decode the command, and control respective blocks of the DDI 200 to perform operation according to the command. The power supply circuit 204 may generate a drive voltage under the control by the controller 202. The driver block 206 may drive a display panel 224 by using the drive voltage generated by the power supply circuit 204 under the control by the controller 202. The display panel 224 may be a liquid crystal display panel or a plasma display panel. The memory block 208 may temporarily store commands input to the controller 202 or control signals output from the controller 202 or store necessary data and may include a memory, such as a random access memory (RAM) or read only memory (ROM). The power supply circuit 204 and the driver block 206 may each Ide one or more of the semiconductor devices 100 and 101 according to the embodiments described above with reference to FIG. 1 to FIG. 5.

FIG. 9 is a block diagram of an electronic system including a semiconductor device according to the embodiment.

Referring to FIG. 9, an electronic system 300 may include a memory 310 and a memory controller 320. The memory controller 320 may control the memory 310 to read data from the memory 310 and/or write data to the memory 310 in response to a request from a host 330. At least one of the memory 310 and the memory controller 320 may include the semiconductor device 100 or 101 according to the embodiment described above with reference to FIG. 1 to FIG. 5.

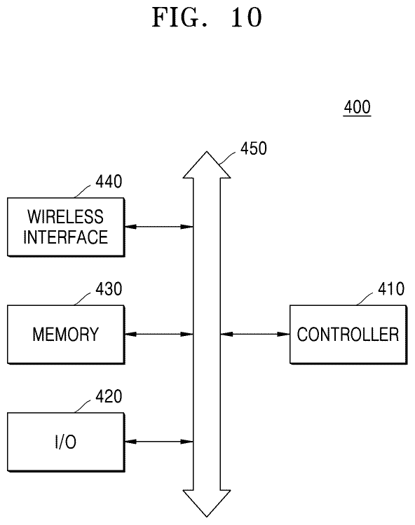

FIG. 10 is a block diagram of an electronic system including a semiconductor device according to at least one embodiment.

Referring to FIG. 10, an electronic system 400 may configure a wireless communication device, or a device capable of transmitting and/or receiving information in a wireless environment. The electronic system 400 may include a controller 410, an input/output device (I/O) 420, a memory 430, and a wireless interface 440, which are connected to each other through a bus 450.

The controller 410 may include at least one of a microprocessor, a digital signal processor, and a processing device similar thereto. The input/output device 420 may include at least one of a keypad, a keyboard, and a display. The memory 430 may store commands executed by the controller 410. For example, the memory 430 may store user data. The electronic system 400 may use the wireless interface 440 to transmit and/or receive data through a wireless communication network. The wireless interface 440 may include an antenna and/or a wireless transceiver. In some embodiments, the electronic system 400 may be used for a communication interface protocol of a third generation communication system, such as code division multiple access (CDMA), global system for mobile communication (GSM), north American digital cellular (NADC), extended-time division multiple access (E-TDMA), and/or wide band code division multiple access (WCDMA). The electronic system 400 may include at least one of the semiconductor devices 100 and 101 according to the embodiments described above with reference to FIG. 1 to FIG. 5.

According to the disclosure, a semiconductor device having a dual gate structure may be provided, and a method of manufacturing the semiconductor device may be provided in which a manufacturing process may be simplified by forming a gate via to electrically connect a plurality of gate electrodes to each other before a channel layer is formed. Although a semiconductor device and a method of manufacturing the semiconductor device are described above with reference to the embodiments illustrated in the drawings, the semiconductor device and the method are merely examples, and those skilled in the art will understand that various modifications and equivalent other embodiments may be derived therefrom. Therefore, the disclosed embodiments should be considered from an illustrative perspective rather than a restrictive perspective. The scope of rights is indicated in the claims, not in the foregoing descriptions, and all differences within the scope equivalent thereto should be interpreted as being included in the scope of the rights.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed

1. A semiconductor device comprising:
a source electrode on a substrate;
a drain electrode on the substrate and spaced apart from the source electrode;
a channel layer connecting the source electrode to the drain electrode and including a two-dimensional material;
a plurality of first gate electrodes on the channel layer and at least partially between the source electrode and the drain electrode, the plurality of first gate electrodes extending in a first direction, and separated from each other in a second direction that is different from the first direction and away from the substrate; and
a first gate via extending in the second direction and connected to one end of each of the plurality of first gate electrodes such that the plurality of first gate electrodes are electrically connected to each other.

2. The semiconductor device of claim 1, wherein the plurality of first gate electrodes are connected to one surface of the first gate via and are not connected to a surface opposite to the one surface.

3. The semiconductor device of claim 1, further comprising:
a plurality of second gate electrodes extending in the first direction and respectively between the plurality of first gate electrodes.

4. The semiconductor device of claim 3, further comprising:
a second gate via connected to the plurality of second gate electrodes such that the plurality of second gate electrodes are electrically connected to each other.

5. The semiconductor device of claim 3, wherein the channel layer is between corresponding ones of the plurality of first gate electrodes and the plurality of second gate electrodes.

6. The semiconductor device of claim 3, further comprising:
a second gate insulating layer between the plurality of second gate electrodes and the channel layer.

7. The semiconductor device of claim 1, wherein the channel layer is between each of the plurality of first gate electrodes.

8. The semiconductor device of claim 1, wherein the channel layer surrounds four side surfaces of at least one of the plurality of first gate electrodes.

9. The semiconductor device of claim 1, further comprising:
a first gate insulating layer between the plurality of first gate electrodes and the channel layer.

10. The semiconductor device of claim 9, wherein the first gate insulating layer surrounds four side surfaces of at least one of the plurality of first gate electrodes.

11. The semiconductor device of claim 1, wherein the channel layer includes three or less layers.

12. The semiconductor device of claim 1, wherein the channel layer includes a transition metal dichalcogenide (TMD).

13. The semiconductor device of claim 12, wherein the TMD includes at least one of Mos₂, WSe₂, MoSe₂, or WS₂.

14. A method of manufacturing a semiconductor device, the method comprising:
forming, on a substrate, a plurality of first gate electrodes such that the plurality of first gate electrodes extend in a first direction and are separated from each other in a second direction that is different from the first direction and away from the substrate;
forming a first gate via such that the first gate via extends in the second direction and electrically connects the plurality of first gate electrodes to each other;
forming a first gate insulating layer such that the first gate insulating layer surrounds the first gate via and at least one of the plurality of first gate electrodes;
forming a channel layer on the first gate insulating layer; and
forming a source electrode and a drain electrode such that the source electrode and the drain electrode are spaced from each other with the plurality of first gate electrodes therebetween.

15. The method of claim 14, further comprising:
forming a second gate insulating layer such that the second gate insulating layer is in contact with the channel layer; and
forming a plurality of second gate electrodes extending in the first direction and respectively between the plurality of first gate electrodes.

16. The method of claim 14, wherein the forming of the source electrode and the drain electrode comprises:
forming a dummy layer surrounding the channel layer;
forming a contact hole by etching the dummy layer through a dry etching process;
expanding the contact hole by etching the dummy layer through an isotropic etching process; and
depositing a metal into the contact hole.

17. The method of claim 16, wherein the dummy layer includes at least one of silicon oxide, aluminum oxide, or silicon nitride.

18. The method of claim 15, further comprising:
forming a second gate via such that the second gate via electrically connects the plurality of second gate electrodes to each other.

19. The method of claim 14, wherein the forming the channel layer includes forming the channel layer to surround four side surfaces of each of the plurality of first gate electrodes.

20. The method of claim 14, wherein the channel layer includes a transition metal dichalcogenide (TMD).
